(19) United States
(12) Patent Application Publication
(10) Pub. No.: US 2013/0135808 A1
(43) Pub. Date: May 30, 2013

(54) PORTABLE ELECTRONIC DEVICE

(71) Applicant: Cheng-Chin Huang, Taipei City (TW)

(72) Inventor: Cheng-Chin Huang, Taipei City (TW)

(73) Assignee: INVENTEC CORPORATION, Taipei City (TW)

(21) Appl. No.: 13/331,858

(22) Filed: Dec. 20, 2011

(30) Foreign Application Priority Data
Nov. 28, 2011 (CN) 201110384237.0

(51) Int. Cl. H05K 7/00

(52) U.S. Cl. 361/679.09

(57) ABSTRACT

A portable electronic device includes a casing, a keyboard, and a latching member. The casing has an upper surface, a lower surface, and a notch extending from the upper surface to the lower surface. The keyboard is detachably configured on the upper surface. The keyboard has a latching slot passing through the notch and protruding from the lower surface. The latching member is movably disposed on the lower surface and spans two opposite sides of the notch. The latching member moves between a first position and second position with respect to the keyboard, wherein when the latching member moves to the first position, the latching member is fastened in the latching slot of the keyboard.

### CROSS-REFERENCE TO RELATED APPLICATION

This application claims the priority benefit of China application serial no. 201110384237.0, filed on Nov. 28, 2011. The entirety of the above-mentioned patent application is hereby incorporated by reference herein and made a part of this specification.

### BACKGROUND OF THE INVENTION

1. Field of the Invention

The present invention generally relates to a portable electronic device, in particular, to a portable electronic device having a fastener module.

2. Description of Related Art

At present, with the gradual development of the technology and the progress of the process technology, the product of each kind is miniaturized as much as possible at the same time with desirable functions and quality, so that the product is conveniently moved or carried. Particularly, as for a notebook computer, each manufacturer tries his best to miniaturize the size to meet the requirements of most of the clients. However, in most of the used manners, more manpower and cost are incurred to dig into the miniaturization of the electronic elements in the notebook computer with unchanged functions, or even increased functions. If such a manner succeeds, the objective may be achieved, but much time, more manpower and high cost are taken.

Here, a structure for supporting the keyboard in the notebook computer is taken as an example. A metal plate on an upper casing is used to supporting frame the keyboard. However, no hook structure exists in a central position of the metal plate to hook the keyboard, so the keyboard fluctuates. In addition, when a user taps the keyboard which is above an optical disk drive, the keyboard may be deformed and depressed downwards due to the tapping force, which affects the operation of the optical disk drive configured below the keyboard. Moreover, when the user taps the keyboard, the user may not have a solid sense of touch due to the fluctuation of the keyboard. Therefore, in the limited space between the keyboard and the optical disk drive, how to design a structure to prevent the keyboard from fluctuating is an issue to be solved at present.

### SUMMARY OF THE INVENTION

Accordingly, the present invention is directed to a portable electronic device, which can fix a keyboard onto a casing through a latching member and effectively prevent the keyboard from fluctuating.

The present invention provides a portable electronic device, which includes a casing, a keyboard, and a latching member. The casing has an upper surface, a lower surface, and a notch extending from the upper surface to the lower surface. The keyboard is detachably configured on the upper surface. The keyboard has a latching slot passing through the notch and protruding from the lower surface. The latching member is movably disposed on the lower surface and spans two opposite sides of the notch. The latching member moves between a first position and second position with respect to the keyboard, wherein when the latching member moves to the first position, the latching member is fastened in the latching slot of the keyboard.

In an embodiment of the present invention, the casing includes a main body and a supporting frame. The main body has an opening. The supporting frame is assembled to the main body and covers the opening. The main body and the supporting frame form the upper surface and the lower surface, and the supporting frame has the notch.

In an embodiment of the present invention, the portable electronic device further includes an optical disk drive which is disposed in the casing, and the supporting frame is located between the optical disk drive and the keyboard.

In an embodiment of the present invention, the portable electronic device further includes a bearing member which is configured on the lower surface of the supporting frame, and the latching member is movably disposed between the bearing member and the supporting frame.

In an embodiment of the present invention, the latching member has at least one pair of propping portions, and the pair of the propping portions is coupled to the supporting frame at the notch, so that the latching member just faces the notch.

In an embodiment of the present invention, the latching member further has a plurality of contacting protrusions in contact with a lateral edge of the notch.

In an embodiment of the present invention, a normal projection of the contacting protrusions on the lower surface is within a range of the notch, and a normal projection of the propping portions on the lower surface is out of the range of the notch.

In an embodiment of the present invention, the latching member further has an insertion portion, and the latching slot is on a moving path of the insertion portion.

In an embodiment of the present invention, the latching member further has an elastic arm and a positioning protruding point disposed on the elastic arm, the bearing member has two positioning recesses, and the positioning protruding point is in cooperation with the positioning recesses so that the latching member moves between the first position and the second position.

In an embodiment of the present invention, the latching member has a hole located between the positioning protruding point and the insertion portion, and a tool is suited for being inserted into the hole to push the latching member to move between the first position and the second position.

On the basis of the above description, in the portable electronic device of the present invention, the latching member is configured between the keyboard and the casing to firmly fix the keyboard onto the casing. Therefore, when the user taps the keyboard, the keyboard does not fluctuate. The latching member of the present invention can effectively prevent the keyboard from depressing when the user taps the keyboard, so the operation of the optical disk drive configured below the keyboard is not affected when the user taps the keyboard. The latching member of the present invention is thinned, so when the latching member is assembled between the casing and the keyboard, the thinning design of the portable electronic device can be maintained in the same way.

In order to make the aforementioned features and advantages of the present invention more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a portable electronic device according to an embodiment of the present invention.

FIG. 2 is a schematic view of a latching member of the portable electronic device in FIG. 1.

FIG. 3A is a schematic view of the latching member in FIG. 2 fastened to a keyboard.

FIG. 3B is a sectional view of FIG. 3A.

FIG. 4A is a schematic view of the latching member in FIG. 2 not fastened to the keyboard.

FIG. 4B is a sectional view of FIG. 4A.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

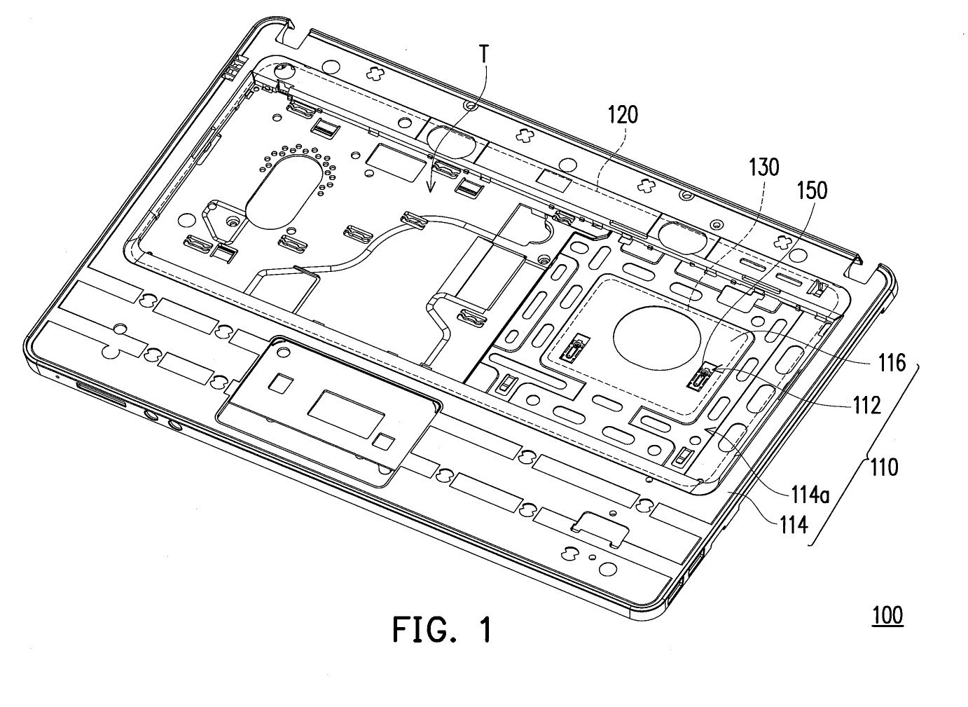

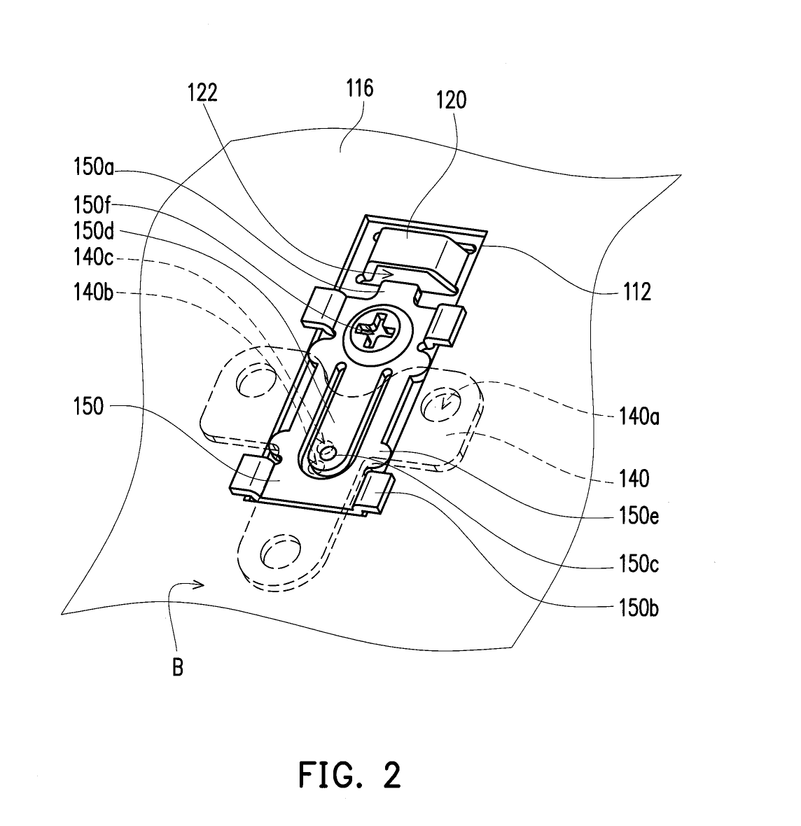

FIG. 1 is a schematic view of a portable electronic device according to an embodiment of the present invention. Referring to FIG. 1, in this embodiment, the portable electronic device 100 includes a casing 110, a keyboard 120 and a latching member 150. The portable electronic device 100 further includes a display unit (not shown), and may be, for example a notebook computer. The casing 110 of this embodiment is used to bear some hardware apparatus (not shown) of the portable electronic device 100, and the hardware apparatus may be, for example, a main board, a Central Processing Unit (CPU), a hard disk, an audio-video playing hardware, a data storage card, a power supplier, a heat sink and the like. The casing 110 has an upper surface T, a lower surface B (referring to FIG. 2) and a notch 112 extending from the upper surface T to the lower surface B, and includes a main body 114 and a supporting frame 116. The main body 114 has an opening 114a, and the supporting frame 116 is assembled to the main body 114 and covers the opening 114a. Therefore, the main body 114 and the supporting frame 116 form the upper surface T and the lower surface B, and the supporting frame 116 has the notch 112. The supporting frame 116 is used to separate an optical disk drive 130 and the keyboard 120. Generally speaking, the keyboard 120 is fixed onto the casing 110 through screws around the casing 110. However, in order to firmly hook the keyboard 120, in this embodiment, besides the above fixing manner, a latching member 150 is configured between the keyboard 120 and the casing 110. Therefore, the latching member 150 is used to fasten the keyboard 120 onto the casing 116. In addition, the latching member 150 may be configured according to the requirements, so the present invention does not limit the number of the configured latching members 150. In this embodiment, as shown in FIG. 1, for example, two latching members 150 are configured.

FIG. 2 is a schematic view of a latching member of the portable electronic device in FIG. 1. In order to clearly show the latching member 150, FIG. 2 illustrates the latching member 150 seen from the lower surface B of the casing 110. Referring to FIG. 1 and FIG. 2, in this embodiment, the supporting frame 116 has a notch 112, and is fixed onto the casing 110 and is exposed from the opening 114a. The portable electronic device 100 further includes an optical disk drive 130 disposed in the casing 110 and just below the supporting frame 116. The keyboard 120 is configured on the upper surface T of the casing 110 and has a latching slot 122. The latching slot 122 corresponds to the notch 112 and protrudes towards the lower surface B of the casing 110. The latching member 150 is movably configured on the lower surface B and spans two opposite sides of the notch 112. The latching member 150 moves between a first position P1 and a second position P2 with respect to the keyboard 120. When the latching member 150 moves to the first position P1, the latching member 150 is fastened in the latching slot 122 of the key board 120. Therefore, the keyboard 120 may be more firmly fixed on the supporting frame 116 through the latching member 150. The latching member 150 and the configuration manner thereof are described in further detail in the following.

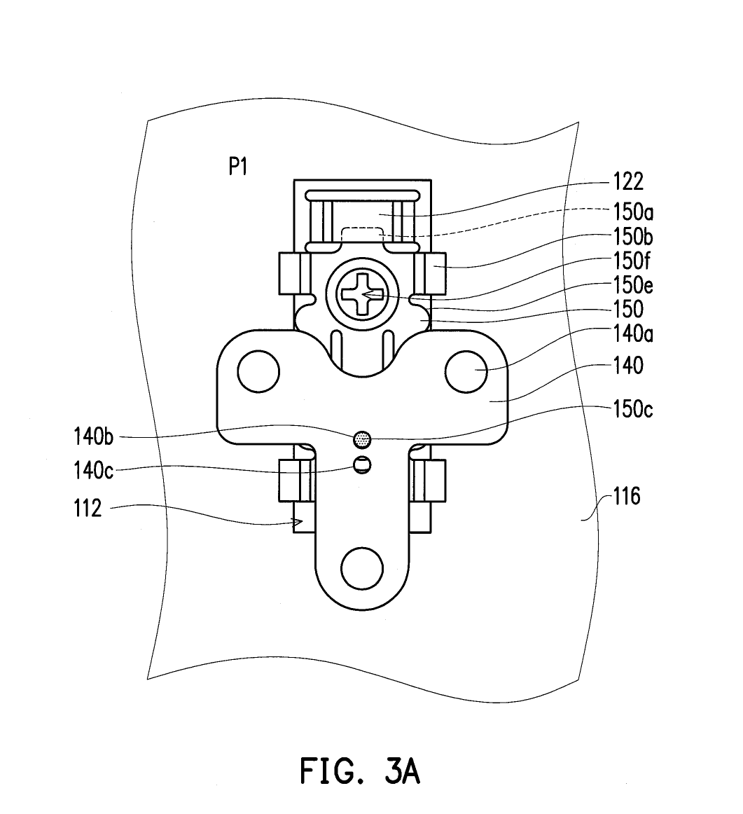

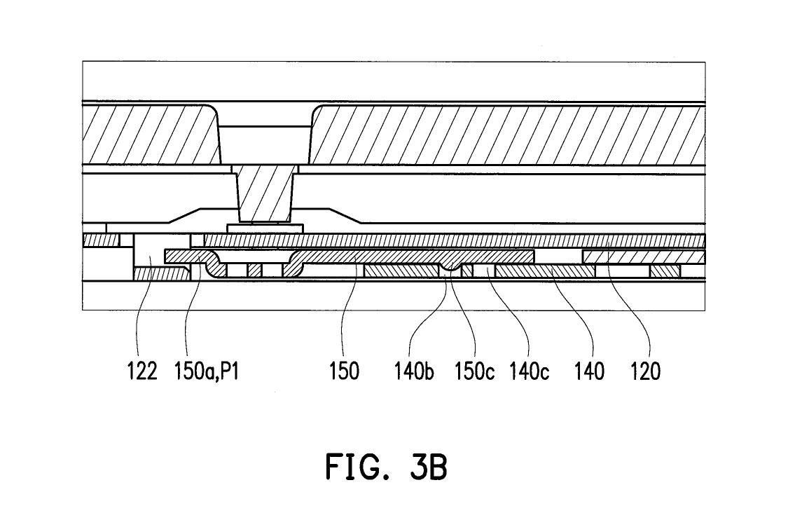

FIG. 3A is a schematic view of the latching member in FIG. 2 fastened to a keyboard, and FIG. 3B is a sectional view of FIG. 3A. In order to more clearly describe a structure of the latching member, FIG. 3A is a schematic view of the latching member 150 seen from the lower surface B of the casing 110 and the notch 112 of the supporting frame 116. Referring to FIG. 3A and FIG. 3B, the portable electronic device 100 further includes a bearing member 140. The bearing member 140 is used as a bearing board enabling the latching member 150 to be clamped between the supporting frame 116 and the bearing member 140. Therefore, the bearing member 140 is fixed onto the supporting frame 116 through the lower surface B of the casing 110 and is exposed from the notch 112.

To clearly show the structure and shape of the latching member 150, the bearing member 140 in FIG. 2 is shown in dotted lines. Referring to FIG. 2, FIG. 3A and FIG. 3B, in this embodiment, the bearing member 140 is a T-shaped board member with each end having a positioning hole 140a, and the bearing member 140 may be fixed onto an edge of the notch 112 of the supporting frame 116 by using screws through the positioning hole 140a. However, as long as the bearing member 140 can enable the latching member 150 to be clamped into the notch 112 of the supporting frame 116, the present invention does not limit the shape of the bearing member 140 and the manner of fixing the bearing member 140 to the supporting frame 116. The latching member 150 has an insertion portion 150a. The latching slot 122 is on a moving path of the insertion portion 150a. The insertion portion 150a is used to be inserted into the latching slot 122 of the keyboard 120.

In this embodiment, in order to enable the latching member 150 to steadily slide on the supporting frame 116, at least one pair of propping portions 150b is respectively configured on two sides of the latching member 150 and is coupled to the supporting frame 116 at the notch 112, so that the latching member 150 just faces the notch 112. Moreover, a normal projection of the propping portions 150b on the lower surface B is out of the range of the notch 112. In other words, the propping portions 150b is used to prop against the edges of the notch 112 of the supporting frame 116 so that the latching member 150 slides on the notch 112 of the supporting frame 116. In addition, the latching member 150 of this embodiment is designed to a sheet structure same as the bearing member 140, so as to conform to the thinning design of the portable electronic device 100. However, it should be noted that, as long as the latching member 150 can be clamped between the bearing member 140 and the supporting frame 116 to slide and inserted into the latching slot 122 of the keyboard 120 so that the keyboard 120 is fastened to the notch 112 of the supporting frame 116, the present invention does not limit the shape of the insertion portion 150a of the latching member 150 and the number of the propping portions 150b.

Referring to FIG. 2, when the latching member 150 slides on the edges of the notch 112 of the supporting frame 116 through the propping portions 150b, in order that the latching member 150 does not turn aside and in order that the latching member 150 slides more steadily, two pairs of contacting protrusions 150e are respectively disposed on two sides of the latching member 150, and a normal projection of the contacting protrusions 150e on the lower surface B is within a range of the notch 112. The contacting protrusions 150e are mainly used to improve the stability and straightness of the latching member 150 when the latching member 150 slides at the notch 112. In other words, when the latching member 150 slides at the notch 112 along the edges of the notch 112, the contacting protrusions 150e prop against an inner wall of the notch 112, so that the latching member 150 does not turn aside with respect to a direction perpendicular to the sliding path. In this embodiment, as shown in FIG. 2, each of the contacting protrusions 150e is designed into a semicircle. However, the present invention does not limit the shape and number of the contacting protrusions 150e.

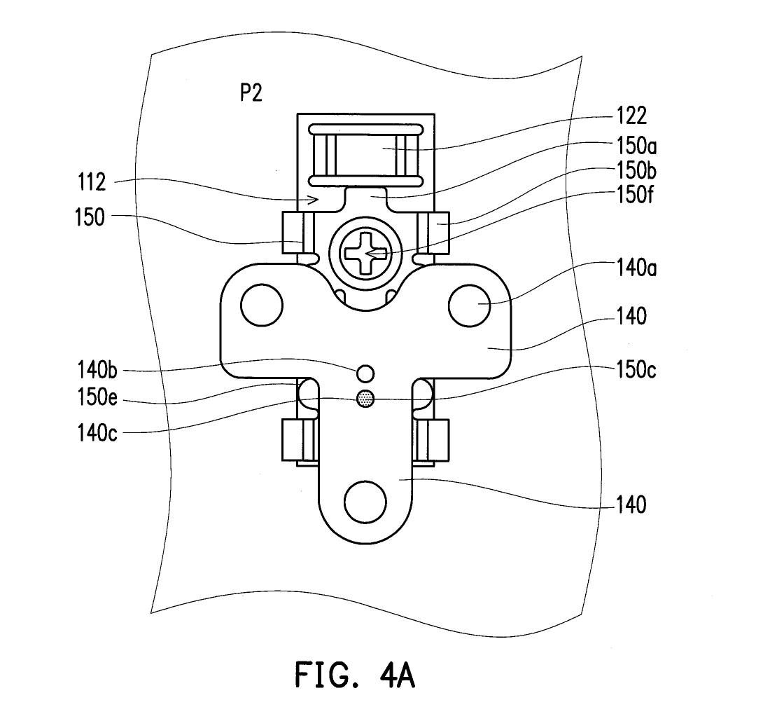

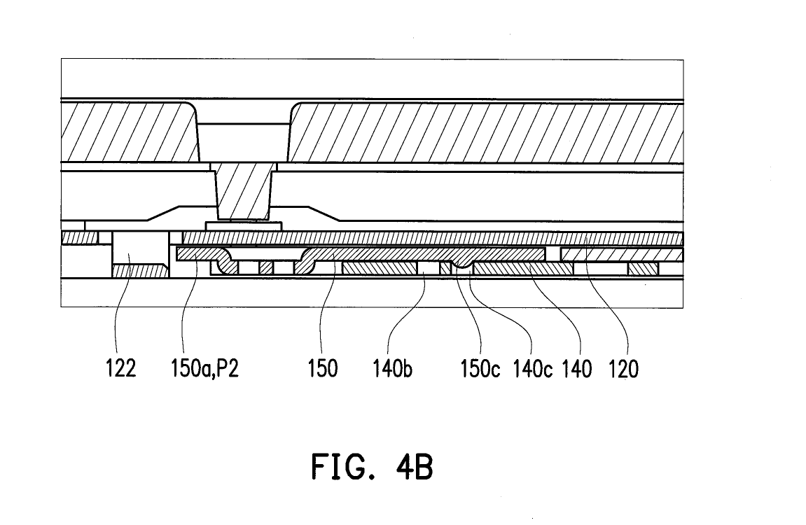

In this embodiment, after the bearing member 140 is fixed onto the supporting frame 116, the latching member 150 presses against the edges of the notch 112 of the supporting frame 116 through the propping portions 150b, and is clamped between the supporting frame 116 and the bearing member 140, so as to complete the configuration of the latching member 150. Through the configuration, the latching member 150 of this embodiment may move between the first position P1 and the second position P2 (as shown in FIG. 4A) with respect to the keyboard 120.

Specifically, as shown in FIG. 3A and FIG. 3B, the insertion portion 150a is inserted into the latching slot 122 of the keyboard 120 by pushing the latching member 150, so that the keyboard can be firmly hooked. When the insertion portion 150a of the latching member 150 is inserted into the latching slot 122 of the keyboard 120, which is defined as a first position. P1 of the latching member 150 in this embodiment, that is, when the latching member 150 is at the first position P1, the latching member 150 is fastened to the latching slot 122 of the keyboard 120. At this time, the keyboard 120 is fastened to the supporting frame 116 by the latching member 150, and the keyboard 120 does not fluctuate. Therefore, the keyboard 120 is firmly fixed onto the supporting frame 116, and the user may have a solid sense of touch when tapping the keyboard 120. Furthermore, when the user taps the keyboard 120, the operation of the optical disk drive 130 configured just below the supporting frame 116 is not affected.

FIG. 4A is a schematic view of the latching member in FIG. 2 not fastened to the keyboard, and FIG. 4B is a sectional view of FIG. 4A. Referring to FIG. 4A and FIG. 4B, in this embodiment, the latching member 150 may slide between the first position P1 and the second position P2 with respect to the keyboard 120. In this embodiment, the position of the latching member 150 when the insertion portion 150a of the latching member 150 is not inserted into the latching slot 122 of the keyboard 120 is defined as the second position P2. Therefore, as shown in FIG. 4A and FIG. 4B, when the latching member 150 is at the second position P2, the latching member 150 is not clamped to the latching slot 122 of the keyboard 120. Therefore, if it is required to separate the keyboard 120 and the latching member 150, the latching member 150 is pushed to the second position P2 so that the insertion portion 150a is separated from the latching slot 122 of the keyboard 120.

It should be noted that, when the user pushes the latching member 150 so that the latching member 150 slides between the first position P1 and the second position P2 with respect to the keyboard 120, in order that the first position P1 and the second position P2 of the latching member 150 are more precise, the latching member 150 of this embodiment further includes a positioning protruding point 150c and an elastic arm 150d, and the positioning protruding point 150c is on the elastic arm 150d. The bearing member 140 further includes two positioning recesses 140b and 140c, and the positioning protruding point 150c is in cooperation with the two positioning recesses 140b and 140c so that the latching member 150 moves between the first position P1 and the second position P2. Specifically, in this embodiment, a positioning protruding point 150c is configured on the elastic arm 150d and is on an overlapping path of the latching member 150 and the bearing member 140 when the latching member 150 slides. The bearing member 140 is further configured with two positioning recesses 140b and 140c which respectively correspond to the first position P1 and the second position P2 of the latching member 150. In other words, when the latching member 150 is at the first position P1, that is, when the insertion portion 150a is inserted into the latching slot 122 of the keyboard 120, the positioning protruding point 150c is inserted into the positioning recess 140b, so as to ensure that the latching member 150 is at the first position P1. When the latching member 150 is at the second position P2, that is, when the insertion portion 150a is separated from the latching slot 122 of the keyboard 120, the positioning protruding point 150c is inserted into the positioning recess 140c, so as to ensure that the latching member 150 is at the second position P2.

It should be noted that, in this embodiment, the positioning protruding point 150c of the latching member 150 and the positioning recesses 140b and 140c of the bearing member 140 are mainly used to further position the latching member 150. Therefore, in other embodiments, the positioning protruding point 150c may be configured on the bearing member 140, and the positioning recesses 140b and 140c may be configured on the latching member 150, as long as the positioning protruding point 150c and the positioning recesses 140b and 140c are in cooperation with each other so as to position the latching member 150 when the latching member 150 slides between the first position P1 and the second position P2. Therefore, the present invention does not limit the shape and the configuration manner of the positioning protruding point 150c, and the positioning recesses 140b and 140c.

In addition, when the latching member 150 slides between the first position P1 and the second position P2, in order to strengthen the functions of the positioning protruding point 150c, and the positioning recesses 140b and 140c, the latching member 150 of this embodiment are designed into elastic sheet structures. Specifically, as shown in FIG. 2, a method for designing the latching member 150 to be an elastic sheet is that, the position having the positioning protruding point 150c is formed into a sheet shape having elasticity, that is, an elastic arm 150d. For example, a latching slot is formed around the positioning protruding point 150c of the latching member 150, that is, partial materials are removed so that the portion of the latching member 150 and having the positioning protruding point 150c is formed into a U-shaped groove, and the shape enables the elastic arm 150d to be elastic to some extent.

In this embodiment, in order that the user conveniently pushes the latching member 150 so that the latching member 150 slides between the first position P1 and the second position P2 with respect to the keyboard 120, the latching member 150 has a hole 150f configured at a position not overlapping with the bearing member 140. The user may push the latching member 150 through the hole 150f so that the insertion portion 150a of the latching member 150 is inserted into or separated from the latching slot 122 of the keyboard 120. During pushing, the user may insert a pen or a shaft into the hole 150f of the latching member 150 to push the latching member 150. In addition, a Phillips screwdriver is frequently used when the portable electronic device 100 is assembled, the hole 150f may be designed into a crisscross shape, so that the user can conveniently insert the Phillips screwdriver into the hole 150f. However, the present invention does not limit the shape and configuration manner of the hole 150f. In addition, the latching member 150, the bearing member 140 and the supporting frame 116 of this embodiment may be integrally formed respectively, and the present invention does not limit the manner.

On the basis of the above description, in the portable electronic device of the present invention, the latching member is configured between the keyboard and the casing to firmly fix the keyboard onto the casing. Therefore, when the user taps the keyboard, the keyboard does not fluctuate. The latching member of the present invention can effectively prevent the keyboard from depressing when the user taps the keyboard, so the operation of the optical disk drive configured below the keyboard is not affected when the user taps the keyboard. The latching member of the present invention is thinned, so when the latching member is assembled between the casing and the keyboard, the thinning design of the portable electronic device can be maintained in the same way. In addition, the latching member of the present invention is easy to operate, and is convenient to be assembled to the casing, so the quality of the portable electronic device is dramatically improved.

The technical content of the present invention has been disclosed through preferred embodiments, but is not intended to be limited thereto. Various variations and modifications made by persons skilled in the art without departing from the spirit of the present invention fall within the scope of the present invention as defined by the appended claims.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A portable electronic device, comprising:
a casing, comprising an upper surface, a lower surface, and a notch extending from the upper surface to the lower surface;
a keyboard, detachably configured on the upper surface, and comprising a latching slot, wherein the latching slot passes through the notch and protrudes from the lower surface; and
a latching member, movably disposed on the lower surface and spanning two opposite sides of the notch, wherein the latching member moves between a first position and a second position with respect to the keyboard, and when the latching member moves to the first position, the latching member is fastened in the latching slot of the keyboard.

2. The portable electronic device according to claim 1, wherein the casing comprises:
a main body, comprising an opening; and
a supporting frame, assembled to the main body and covering the opening, wherein the main body and the supporting frame form the upper surface and the lower surface, and the supporting frame comprises the notch.

3. The portable electronic device according to claim 2, further comprising:
an optical disk drive, disposed in the casing, wherein the supporting frame is between the optical disk drive and the keyboard.

4. The portable electronic device according to claim 2, further comprising:
a bearing member, configured on the lower surface of the supporting frame, wherein the latching member is movably disposed between the bearing member and the supporting frame.

5. The portable electronic device according to claim 2, wherein the latching member comprises at least one pair of propping portions, and the pair of propping portions is coupled to the supporting frame at the opening, so that the latching member just faces the notch.

6. The portable electronic device according to claim 5, wherein the latching member further comprises a plurality of contacting protrusions in contact with lateral edges of the notch.

7. The portable electronic device according to claim 6, wherein a normal projection of the contacting protrusions on the lower surface is within a range of the notch, and a normal projection of the propping portions on the lower surface is out of the range of the notch.

8. The portable electronic device according to claim 2, wherein the latching member further comprises an insertion portion, and the latching slot is on a moving path of the insertion portion.

9. The portable electronic device according to claim 8, wherein the latching member further comprises an elastic arm and a positioning protruding point on the elastic arm, the bearing member comprises two positioning recesses, and the positioning protruding point is in cooperation with the positioning recesses so that the latching member moves between the first position and the second position.

10. The portable electronic device according to claim 9, wherein the latching member further comprises a hole between the positioning protruding point and the insertion portion, and a tool is suited for being inserted into the hole to push the latching member to move between the first position and the second position.
